(19) United States
(12) Patent Application Publication
(10) Pub. No.: US 2017/0323910 A1
(43) Pub. Date: Nov. 9, 2017

(54) DISPLAY DEVICE AND MANUFACTURING METHOD THEREOF

(71) Applicant: SAMSUNG DISPLAY CO., LTD., YONGIN-SI (KR)

(72) Inventors: JUN HYUN PARK, Suwon-si (KR); Sung Hwan KIM, Yongin-si (KR); Kyoung Ju SHIN, Hwaseong-si (KR)

(21) Appl. No.: 15/492,465

(22) Filed: Apr. 20, 2017

(30) Foreign Application Priority Data
May 4, 2016 (KR) 10-2016-0055357

(51) Int. Cl. H01L 27/12; H01L 27/32; G09G 3/36; G09G 3/3266

(52) U.S. Cl. CPC H01L 27/1255; H01L 27/3276; H01L 27/3265; G09G 3/3266; H01L 27/124; G09G 3/3677; H01L 27/3262

(57) ABSTRACT

A display device and method of manufacture includes a substrate; a transistor disposed on the substrate to include a gate electrode, a semiconductor layer, a source electrode, a drain electrode, and a gate insulating layer disposed between the gate electrode and the semiconductor layer. A capacitor disposed on the substrate includes a first electrode, a second electrode, and a dielectric layer is disposed between the first electrode and the second electrode. The dielectric layer has a thickness that is thinner than a thickness of the gate insulating layer.

### CROSS-REFERENCE TO RELATED APPLICATIONS

This application claims priority from and the benefit of Korean Patent Application No. 10-2016-0055357 filed in the Korean Intellectual Property Office on May 4, 2016, the entire contents of which are incorporated by reference herein.

### TECHNICAL FIELD

This disclosure relates to a display device and a manufacturing method thereof.

### DISCUSSION OF THE RELATED ART

A display device, such as a liquid crystal display device (LCD) and an organic light emitting diode (OLED) display, includes a display panel on which an image is displayed, a gate driver for driving the display panel, and a driver such as a data driver. The gate driver may be formed as a separate chip, and may be electrically connected to the display panel. A technique of integrating the gate driver on a display panel without a separate chip has been recently developed.

The gate driver may include a transistor used as a switching element and a capacitor used as a storage element. When the gate driver is integrated in the display panel, the gate driver may be disposed in a peripheral area of the display panel, e.g., outside the display area in which the image is displayed. To reduce a bezel width of a display device, the peripheral area of the display panel may be reduced. However, when the gate driver is disposed in the peripheral area of the display panel, there may be a limit in reducing the width of the peripheral area. In addition, an area for forming the capacitor of the gate driver may be limited in accordance with an increase in the resolution of the display device.

### SUMMARY

At least one exemplary embodiment of the inventive concept provides a display device that may be capable of increasing capacitance of a capacitor of the display device and reducing a width of a gate driver.

An exemplary embodiment of the inventive concept provides a display device including: a substrate; a transistor disposed on the substrate that includes a gate electrode, a semiconductor layer, a source electrode, a drain electrode, and a gate insulating layer disposed between the gate electrode and the semiconductor layer; and a capacitor disposed on the substrate that includes a first electrode, a second electrode, and a dielectric layer disposed between the first electrode and the second electrode, wherein the dielectric layer has a thickness that is thinner (e.g. less) than the gate insulating layer.

In an embodiment of the inventive concept, the substrate may include a display area in which a plurality of pixels are disposed and a peripheral area in which a gate driver including the transistor and the capacitor is disposed.

In an embodiment of the inventive concept, the dielectric layer of the capacitor is a separate layer from the gate insulating layer.

In an embodiment of the inventive concept, the insulating layer includes at least one contact hole, a first conductive layer comprising gate lines is disposed on the substrate, and a second conductive layer comprising data lines is connected to the first conductive layer through a metal direct connection (MDC) via the at least one contact hole, and the second conductive layer is an extension of the second electrode.

The transistor may further include an etch stop layer disposed on the semiconductor layer, and the dielectric layer may be disposed at a same layer as the etch stop layer.

The dielectric layer may be formed of a same material of the etch stop layer.

The dielectric layer may have a substantially same thickness as the etch stop layer.

The thickness of the dielectric layer may be within a range of about 400 angstroms to about 600 angstroms.

The dielectric layer may be formed as a single layer.

In an embodiment of the inventive concept, the single layer of the dielectric layer is formed of a silicon oxide.

The dielectric layer may include a silicon oxide.

The dielectric layer may have a first surface that contacts an upper surface of the first electrode and a second surface that contacts a lower surface of the second electrode.

The dielectric layer may cover at least one side surface of the first electrode.

The dielectric layer may include a silicon nitride.

The substrate may include a display area in which a plurality of pixels are disposed and a peripheral area in which a gate driver is disposed, and the gate driver may include the transistor and the capacitor.

The first electrode of the capacitor may be connected with the gate electrode of the transistor, and the second electrode of the capacitor may be connected with the drain electrode of the transistor.

An exemplary embodiment provides a manufacturing method of a display device, including: forming a gate electrode of a transistor, a first electrode of a capacitor, and a first conductive layer by depositing a conductive material on a substrate and patterning the conductive material; forming a gate insulating layer by depositing an insulating material; forming a semiconductor layer to overlap the gate electrode by depositing a semiconductor material and patterning the semiconductor material; forming a first contact hole for exposing at least a portion of the first electrode and a second contact hole for exposing at least a portion of the first conductive layer in the gate insulating layer by patterning the gate insulating layer; forming an etch stop layer to overlap the semiconductor layer and a dielectric layer to overlap the first electrode by depositing an insulating material and patterning the insulating material; and forming a second conductive layer that contacts a source electrode and a drain electrode of the transistor, a second electrode of the capacitor, and the first conductive layer by depositing a conductive material and patterning the conductive material.

The dielectric layer may have a thickness that is thinner than that of the gate insulating layer.

The dielectric layer may be formed of an insulating material including a silicon oxide.

The first electrode may be connected with the gate electrode, and the second electrode may be connected with the drain electrode.

An exemplary embodiment of the inventive concept provides a manufacturing method of a display device, including: forming a gate electrode of a transistor, a first electrode of a capacitor, and a first conductive layer by depositing a conductive material on a substrate and patterning the conductive material; forming a gate insulating layer by depositing an insulating material; forming a semiconductor material layer by depositing a semiconductor material; forming a first photosensitive film pattern having portions with different heights, and exposing at least a portion of the first conductive layer by etching the gate insulating layer and the semiconductor material layer using the first photosensitive film pattern as an etching mask; forming a second photosensitive film pattern from the first photosensitive film pattern; forming a dielectric layer of the capacitor by etching a portion of the semiconductor material layer overlapping the first electrode to expose a portion of the gate insulating layer overlapping the first electrode and etching the portion of the gate insulating layer overlapping the first electrode to reduce a thickness thereof using the second photosensitive film pattern as an etching mask; and forming a second conductive layer that contacts a source electrode and a drain electrode of the transistor, a second electrode of the capacitor, and the first conductive layer by depositing a conductive material and patterning the conductive material.

The dielectric layer has a thickness that is thinner than that of the gate insulating layer.

The dielectric layer may be formed of an insulating material including a silicon oxide.

The first electrode may be connected with the gate electrode, and the second electrode may be connected with the drain electrode.

According to the exemplary embodiments of the present inventive concept, it is possible to increase capacitance of the capacitor. Accordingly, since an area occupied by the capacitor included in the gate driver is reduced, the width of the gate driver can be reduced, and the bezel width of the display device can be reduced.

In addition, according to an embodiment of the inventive concept, the capacitance of the capacitor may be increased without an additional mask or process.

In an embodiment of the inventive concept, a display device includes a substrate, a gate driver including a transistor and a capacitor, the transistor disposed on the substrate and includes a gate electrode, a semiconductor layer, a source electrode, a drain electrode, and a gate insulating layer disposed between the gate electrode and the semiconductor layer, the capacitor is disposed on the substrate and includes a first electrode and a second electrode, and a dielectric layer disposed between the first electrode and the second electrode, and the dielectric layer is a separate layer from the gate insulating layer, and a thickness of the dielectric layer is less than a thickness of the gate insulating layer.

### BRIEF DESCRIPTION OF THE DRAWINGS

FIG. 1 schematically illustrates a configuration of a display device according to an exemplary embodiment of the present inventive concept.

FIG. 2 is a layout view illustrating a transistor and a capacitor included in a gate driver of a display device according to an exemplary embodiment of the present inventive concept.

FIG. 3 is a cross-sectional view taken along lines III-III′, IV-IV′ and V-V′ of FIG. 2, illustrating a display device according to an exemplary embodiment of the present inventive concept.

FIG. 4 and FIG. 5 are cross-sectional views illustrating a manufacturing method of the display device shown in FIG. 3.

FIG. 6 is a cross-sectional view corresponding to the cross-sectional view taken along the lines III-III′, IV-IV′, and V-V′ of FIG. 2 according to an exemplary embodiment of the present inventive concept.

FIG. 7 is a cross-sectional view corresponding to the cross-sectional view taken along the lines III-III′, IV-IV′, and V-V′ of FIG. 2 according to an exemplary embodiment of the present inventive concept.

FIG. 8 and FIG. 9 are cross-sectional views illustrating a manufacturing method of the display device of FIG. 7.

FIG. 10 is a block diagram illustrating a gate driver of a display device according to an exemplary embodiment of the present inventive concept.

FIG. 11 is a circuit diagram illustrating a stage of a gate driver according to an exemplary embodiment of the present inventive concept.

### DETAILED DESCRIPTION

The present inventive concept will be described more fully hereinafter with reference to the accompanying drawings, in which exemplary embodiments of the invention are shown. As those skilled in the art would realize, the embodiments discussed herein may be modified in various different ways, all without departing from the spirit or scope of the present inventive concept.

Like reference numerals designate like elements throughout the specification. For terms used in this specification, it will be understood that when an element such as a layer, film, region, or substrate is referred to as being “on” another element, it may be directly on the other element or intervening elements may also be present there between.

In contrast, when an element is referred to as being “directly on” another element, there may be no intervening elements present. Unless otherwise noted in the specification, “overlap” may be defined as having at least part of a layer, film, region, or substrate that overlaps another element when viewed, for example, in a plan view. As used herein, the singular forms, “a,” “an” and “the” are intended to include the plural forms as well, unless the context clearly indicates otherwise.

Hereinafter, a display device according to an exemplary embodiment of the present inventive concept will now be described in detail with reference to the accompanying drawings.

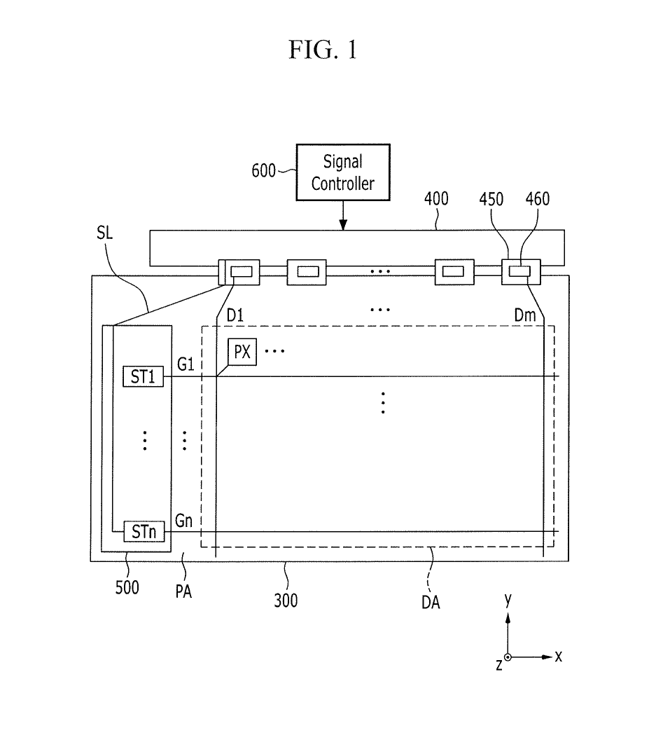

FIG. 1 schematically illustrates a configuration of a display device according to an exemplary embodiment of the present inventive concept.

Referring to FIG. 1, the display device may include, for example, a display panel 300, a data driver 460, a gate driver 500, and a signal controller 600.

The display panel 300 includes a display area DA for displaying an image and a peripheral area PA that is arranged at least partly around the display area DA. In this example, the gate driver 500 applies a gate voltage to the gate lines G1-Gn and the like, and the gate driver is disposed in the peripheral area PA.

The data lines D1-Dm of the display area DA may receive a data voltage from the data driver 460, which may be an integrated circuit (IC) formed on a flexible printed circuit board (FPCB) 450 attached to the display panel 300. The data lines D1-Dm may extend from the display area DA to the peripheral area PA and form at least a portion of a fanout portion (not shown) in the peripheral area PA.

The gate driver 500 and the data driver 460 are controlled by the signal controller 600. A printed circuit board 400 is disposed outside (e.g. arranged adjacent to) the FPCB 450, and may transmit a signal from the signal controller 600 to the data driver 460 and the gate driver 500. A signal provided to the gate driver 500 through the signal lines SL in the signal controller 600 may include signals such as a vertical start signal, a clock signal, and a signal to provide a of a specific level, for example, a logic low voltage VSS1 or VSS2. According to an exemplary embodiment, the signal provided to the gate driver 500 may include various types and quantifies of vertical start signals, clock signals, and/or low voltages.

A plurality of pixels PX are disposed in the display area DA. The display area DA may include a transistor, a storage capacitor, and the like. The storage capacitor stores a charge so that the capacitor may be discharged to maintain a voltage level for a certain period of time, and maintains the applied voltage even after the transistor is turned off. In the case of the liquid crystal display, the display area DA includes a liquid crystal capacitor, and the liquid crystal capacitor includes a pixel electrode, a common electrode, and a liquid crystal layer. The liquid crystal layer may be charged in a corresponding microcavity (not illustrated) for every one of, or some of a plurality of pixel areas. An alignment of liquid crystal directors included in a liquid crystal layer may change depending on an amount of electric charge stored in a liquid crystal capacitor. In the organic light emitting diode display, the display area DA may include a light-emitting device, and the light-emitting device may include a pixel electrode, a common electrode, and an emission layer. A plurality of gate lines G1 to Gn and a plurality of data lines D1 to Dm are disposed in the display area DA. The arrangement of the gate lines G1 to Gn and the data lines D1 to Dm may traverse each other while being insulated from each other.

In the case of the liquid crystal display, there are a plurality of pixels, and, for example, a pixel PX may include a transistor, a liquid crystal capacitor, and a storage capacitor. A control terminal (gate electrode) of the transistor is connected with a gate line, an input terminal (source electrode) of the transistor is connected with a data line, and an output terminal (drain electrode) of the transistor is connected with a first terminal of the liquid crystal capacitor and a first terminal of the storage capacitor. A second terminal of the liquid crystal capacitor may be connected to a common electrode to receive a common voltage, and a second terminal of the storage capacitor receives a storage voltage. In the case of the organic light emitting diode display, a pixel PX may include at least two transistors including a switching transistor and a driving transistor, at least one storage capacitor, and a light-emitting device, and may further include at least one compensation transistor.

With continued refer to FIG. 1, the data lines D1-Dm receive data voltages from the data driver 460, and the gate lines G1-Gn receive gate voltages from the gate driver 500.

The data driver 460 may be disposed at an upper or lower side of the display panel 300 for connection to the data lines D1-Dm.

The gate driver 500 generates gate voltages (e.g. a gate-on voltage and a gate-off voltage) by receiving, for example, low voltages (e.g. logic low) corresponding to a vertical start signal, a clock signal, and a gate-off voltage to apply them to the gate lines G1 to Gn. The gate driver 500 includes a plurality of stages ST1-STn for generating and outputting the gate voltages by using, for example, the vertical start signal, clock signal and gate-off voltage, and a plurality of signal lines SL for transferring the signals to the stages ST1-STn. The signal lines SL may be disposed at further from the display area DA than the stages ST1-STn of the gate driver 500, but the present inventive concept is not limited thereto. For example, some of the signal lines SL may be disposed between the stages ST1-STn and the display area DA, and may be closer to the display area DA than the stages ST1-STn. Although the signal line SL is illustrated by using one line in FIG. 1, the signal lines SL may include a plurality of signal lines corresponding to a number of signals applied to the gate driver 500, and may include more signal lines or less signal lines. The gate driver 500 may be integrated in the peripheral area PA of the display panel 300. According to an exemplary embodiment, the gate driver 500 may be mounted on the printed circuit board or the FPCB in the form of an IC chip that is electrically connected to the display panel 300.

The vertical start signal, the clock signal, and the low voltage may be applied to the gate driver 500 through the FPCB 450. The vertical start signal, the clock signal, and the low voltage signals may be transmitted from the outside, or by the signal controller 600 to the FPCB 450 through the printed circuit board 400.

The gate driver 500 may be disposed, for example, at the left side and/or right side of the display area DA, and may be disposed at the upper side and/or the lower side thereof. When the gate driver 500 is disposed at the left side and the right side of the display panel, the gate driver disposed at the left side of the display panel includes odd-numbered stages ST1, ST3, . . . , and the gate driver disposed at the right side of the display panel may include even-numbered stages ST2, ST4, . . . , or vice versa. However, in the example where the gate driver 500 and the display panel are disposed at the left and right sides, the gate drivers disposed at the left side and the right side may include all the stages ST1 to STn. The stages ST1-STn of the gate driver 500 may include, for example, a plurality of transistors and at least one capacitor. These plurality of transistors and capacitors of the gate driver 500 can be manufactured in a same process as the transistors and the like included in the pixel PX of the display area DA.

The gate electrode and the gate line of the transistor can be formed in the same layer with the same material. Components formed of the same material in the same layer as the gate electrode are referred to as gate conductors. Similarly, the source and drain electrodes of the transistor and the data line may be formed in the same layer with the same material. Components formed of the same material in the same layer as the source electrode and the drain electrode are referred to as data conductors.

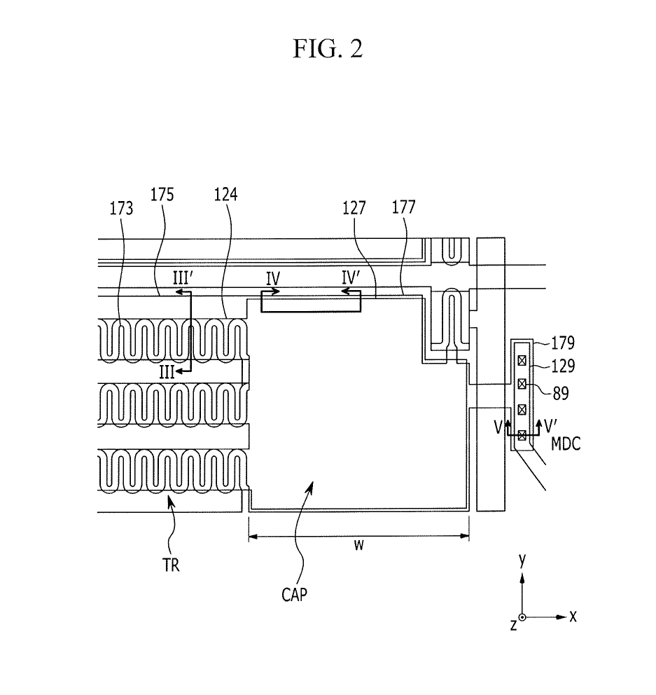

Herein below, a gate driver according to an exemplary embodiment of the present inventive concept will be described in more detail with reference to FIG. 2 to FIG. 5.

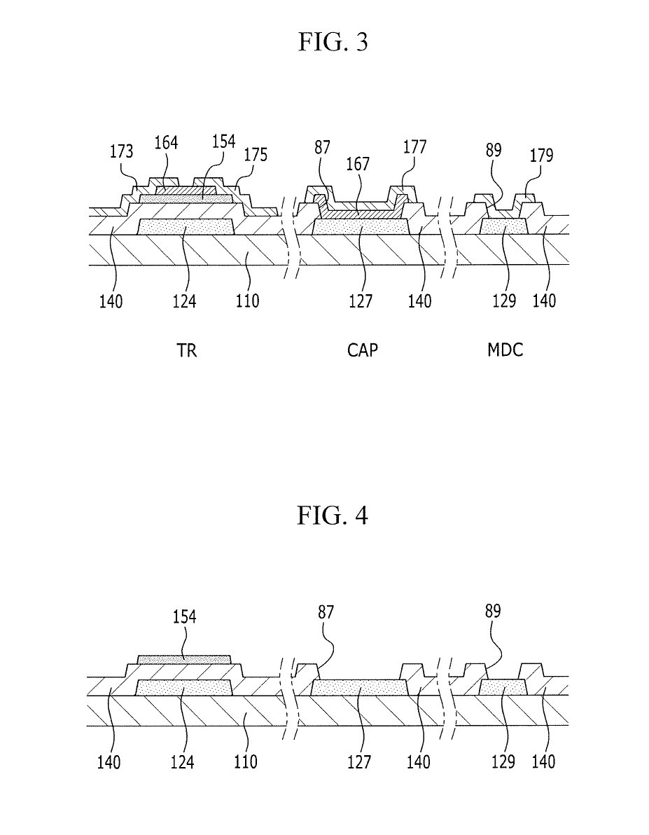

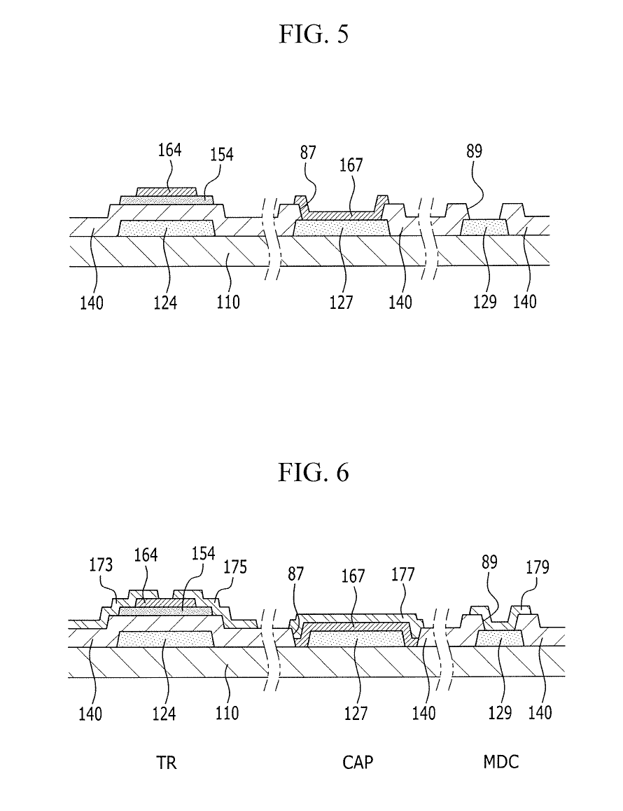

FIG. 2 is illustrates a arrangement of a transistor and a capacitor included in a gate driver of a display device according to an exemplary embodiment of the present inventive concept, FIG. 3 is a cross-sectional view of FIG. 2 taken along lines III-III′, IV-IV′, and V-V′, illustrating a display device according to an exemplary embodiment of the present inventive concept, and FIG. 4 and FIG. 5 are cross-sectional views illustrating a manufacturing method of the display device of FIG. 3.

Referring now to FIG. 2 and FIG. 3, the gate driver according to the exemplary embodiment of the present inventive concept includes a transistor TR and a capacitor CAP. In FIG. 3, a left portion of the drawing corresponds to the transistor TR, a middle portion of the drawing corresponds to the capacitor (CAP), and a right portion of the drawing corresponds to a metal direct connection or metal direct contact (MDC) to be described herein after. When the transistor TR is a pull-up unit of the gate driver to be described later, a first electrode 127 of the capacitor may be connected to a gate electrode 124 of the transistor TR, and a second electrode 177 of the capacitor CAP may be connected to a drain electrode 175 of the transistor TR. More particularly, the second electrode 177 of the capacitor may be connected with a first conductive layer 129 which may serve as a gate line through a conductive layer 179 which may be an extension of the second electrode 177. The gate electrode 124 of the transistor TR, the first electrode 127 of the capacitor CAP, and the first conductive layer 129 are disposed in the same layer; and the source electrode 173 and the drain electrode 175 of the transistor and the second electrode 177 and the second conductive layer 179 of the capacitor are disposed in the same layer.

A structure of the transistor TR and the capacitor CAP will be described in further detail herein below.

Referring to FIG. 3, the gate electrode 124 of the transistor and the first electrode 127 of the capacitor are disposed on an insulating substrate 110 made of a material such as glass or plastic. The first conductive layer 129, such as a gate line, is also disposed on the insulating substrate 110. The gate electrode 124, the first electrode 127, and the first conductive layer 129 are included in a gate conductor, and may be constructed of a metal material. The gate conductor, for example, may be made of a metal such as copper (Cu), aluminum(Al), silver (Ag), molybdenum(Mo), chromium(Cr), tantalum(Ta), titanium(Ti), and a metal alloy thereof. The gate conductor may be formed as one conductive layer, and may be formed as a multilayer structure including at least two conductive layers made of different materials.

A gate insulating layer 140 is disposed on the gate conductor. The gate insulating layer 140 may be formed of an inorganic material such as a silicon nitride (SiNx) or a silicon oxide (SiOx). The gate insulating layer 140 may be constructed of a multi-film structure including at least two insulating films having different physical properties, and may have a double-layer structure of, for example, a lower silicon nitride film and an upper silicon oxide film. The gate insulating layer 140 may have a thickness of, for example, from about 3600 angstroms to about 5400 angstroms, but the thickness is not limited thereto.

The gate insulating layer 140 is not substantially disposed above the first electrode 127 of the capacitor. In other words, the gate insulating layer 140 includes a contact hole 87 and is formed so as to not cover most portions or all portions of the first electrode 127. The gate insulating layer 140 also includes a contact hole 89 and is formed so as to not cover at least a part of the first conductive layer 129.

A semiconductor layer 154 is disposed on the gate insulating layer 140. The semiconductor layer 154 may overlap the gate electrode 124 in a view, e.g., in a direction perpendicular to the substrate 110. The semiconductor layer 154 may be formed of a semiconductor material, e.g. an oxide semiconductor, amorphous silicon, or polycrystalline silicon. When the semiconductor layer 154 is constructed of an oxide semiconductor, the semiconductor layer 154 may be a tetravalent element such as indium (In), gallium (Ga), and/or a group 2B element such as zinc (Zn), and an oxide semiconductor of a minimum of a ternary system (at least three elements including oxygen. For example, the semiconductor layer 154 may be indium-gallium-zinc oxide (IGZO) or indium-tin-zinc oxide (ITZO). The semiconductor layer 154 may be formed as a single layer or a multilayer.

An etch stop layer 164 is disposed on the semiconductor layer 154. The etch stop layer 164 has different etch selectivity for at least one of the semiconductor layer 154 and the data conductor, and prevents a channel region of the semiconductor layer 154 from being damaged in the process of forming the data conductor. Therefore, the etching stopper layer 164 formed on the semiconductor layer may be thin. For example, the etch stop layer 164 may be of a thickness of about a few hundred angstroms, such as about 400 to 600 angstroms, but the thickness of the etch stop layer not limited thereto. In addition, the etch stop layer may be disposed as a dielectric layer 167 on the first electrode 127 of the capacitor.

Thus, the dielectric layer 167 can be made of the same material as the etch stop layer 164. The etch stop layer 164 and the dielectric layer 167 may be made of an inorganic material such as a silicon oxide or a silicon nitride. In addition, the dielectric layer 167 may have a thickness corresponding to a thickness of the etch stop layer 164. For example, the dielectric layer 167 may have substantially the same thickness as the etch stop layer 164 in most regions except for the periphery of the capacitor or in the entire region of the capacitor.

With continued reference to FIGS. 2 and 3, a source electrode 173 and the drain electrode 175 are disposed on the semiconductor layer 154 and the etching stopper layer 164 of the transistor. The second electrode 177 is disposed on the dielectric layer 167 of the capacitor. With regard to the MDC, the second conductive layer 179 is disposed on the first conductive layer 129. The source electrode 173, the drain electrode 175, the second electrode 177, and the second conductive layer 179 are data conductors, and may be constructed of a metal material. The data conductor may be made of, for example, copper (Cu), aluminum (Al), silver (Ag), molybdenum (Mo), chromium (Cr), gold (Au), platinum (Pt), palladium (Pd), tantalum (Ta), tungsten (W), titanium (Ti), nickel (Ni), or the like, or a metal alloy thereof. The data conductor may be formed as a single conductive film, or may be formed as a multilayer including at least two conductive layers made of different materials.

Although not shown, an interdiffusion barrier may be disposed on the semiconductor layer 154. The barrier may be formed of a transparent conductive oxide such as an indium-zinc oxide (IZO) or an indium-tin oxide (ITO). The barrier serves as a diffusion preventing layer for preventing a conductive material such as copper of the source and drain electrodes 173 and 175 from diffusing into the semiconductor layer 154. The barrier may include a metal oxide such as a gallium-zinc oxide or an aluminum-zinc oxide, or a metal such as titanium (Ti), chromium (Cr), tantalum (Ta), or molybdenum (Mo). When the semiconductor layer 154 is made of amorphous silicon, an ohmic contact may be disposed on the semiconductor layer 154. The ohmic contact may be formed of a silicide or a material such as n+ hydrogenated amorphous silicon doped with an n-type impurity such as phosphorus in a high concentration.

As described above, the transistor includes the gate electrode 124, the semiconductor layer 154, the source electrode 173, and the drain electrode 175. The gate insulating layer is located between the gate electrode 124 and the semiconductor layer 154, and the etch stop layer is located between the semiconductor layer 154 and the source electrode 173 and the drain electrode 175. The capacitor includes the first electrode 127, the second electrode 177, and the dielectric layer 167 there between. Since the dielectric layer 167 of the capacitor is formed in a same layer as the etch stop layer 164 of the transistor, a further reduction of the thickness may be possible compared with a case that the dielectric layer 167 is formed as the gate insulating layer 140 or the dielectric layer 167 includes the gate insulating layer 140. For example, when the dielectric layer is formed only of the etch stop layer of a SiOx, for example, with a thickness of 500 Å, the thickness of the dielectric layer can be reduced to 1/9 and the capacitance can be increased by about 6 times as compared with the case of forming the gate insulating layer of a SiNx/SiOx having a thickness of 4000 Å/500 Å and the etch stop layer having a thickness of 500 Å.

As a thickness of the dielectric layer 167 decreases, a distance between the first electrode 127 and the second electrode 177 decreases, to increase the capacitance of the capacitor, so that the capacitance can be maintained or increased even if the area of the capacitor is reduced. Accordingly, since a width w of the capacitor shown in FIG. 2 can be reduced, a width of the gate driver can be reduced in an x-axis direction, and as a result, a width of the bezel of the display device can be reduced. As the resolution of the display device increases, a width of each stage of the gate driving unit in the x-axis direction may be reduced. In this case, increasing the width w of the capacitor may maintain an amount of the capacitance of the capacitor. If the capacitance of the capacitor is reduced at the gate driver, maintaining the capacitance may be a consideration because of noise that may occur at a high temperature. However, in the present exemplary embodiment, since the thickness of the dielectric layer 167 can be reduced to increase the capacitance, the capacitance can be maintained without increasing the width w of the capacitor.

In addition, the thickness of the dielectric layer of the capacitor and a width of the gate driver disposed in the peripheral area have a positive correlation in that as the thickness of the dielectric layer is decreased, the width of the gate driving unit may be reduced.

With continued reference to FIGS. 2 and 3, the second conductive layer 179, which may be an extension of the second electrode 177 of the capacitor, may be connected to the first conductive layer 129, which may be a gate line, through a metal direct connection (MDC). Herein, the metal direct connection indicates a direct connection of a data conductor with a gate conductor both physically and electrically by forming a contact hole between the gate conductor and the data conductor. This metal direct connection may be used for connection between various wires in the peripheral area of the display panel (e.g., connection between the signal line and the stage in the gate driver) in addition to connection of an extension of the second electrode 177 of the capacitor to the gate line. The direct connection of the data conductor to the gate conductor can reduce the area of the connection (e.g., greater than about 50% over the bridge), and thus a bezel width of the display device can be reduced by reducing the width of the peripheral area. The metal contact may also be used for performing a physical and electrical connection between a gate wire which is a gate conductor and a data wire, which is a data conductor, by dually forming a wire as the gate wire and the data wire as one way to reduce the resistance. Thus, the first conductive layer 129 may be any of the gate conductors, such as gate lines, and the second conductive layer 179 may be any of the data conductors, such as data lines.

The transistors and capacitors described herein are not limited to examples shown in the connection relationship, and the transistor, for example, may be a transistor in the gate driver which is not directly connected to the capacitor. Although the transistors and capacitors of the gate driver are described as an example of the inventive concept, the transistors and/or storage capacitors in the display area may also have a structure corresponding to the transistors and/or capacitors described above.

Hereinafter, a manufacturing method of the display device illustrated in FIG. 3 will be described with reference to FIG. 4 and FIG. 5.

Referring to FIG. 4, a conductive material (such as a metal) is stacked on the insulation substrate 110 through sputtering or the like, and a gate conductor including the gate electrode 124, the first electrode 127, and the first conductive layer 129 is formed by performing patterning thereon with a photosensitive material such as a photoresist and a first mask.

Next, an insulating material such as a silicon nitride or a silicon oxide is stacked, for example, on the gate electrode 124, through chemical vapor deposition (CVD) to form the gate insulating layer 140. A semiconductor material such as an oxide semiconductor is stacked on the gate insulating layer 140 through sputtering or the like and patterned using a second mask to form the semiconductor layer 154 overlapping the gate electrode 124. As shown in FIG. 4, the gate insulating layer 140 is then patterned using a third mask to form the contact hole 87 to expose at least a portion of the first electrode 127 and another contact hole 89 to expose at least a portion of the first conductive layer 129. In this case, the contact hole 89 is formed in the gate insulating layer 140 for directly connecting the second conductive layer 179 to the first conductive layer 129, e.g., for a metal direct connection (MDC), and the third mask used to form the contact hole 89 can be used to substantially remove the gate insulating layer 140 on the first electrode 127.

Referring now to FIG. 5, an insulating material such as a silicon oxide or a silicon nitride is stacked through chemical vapor deposition or the like and then patterned using a fourth mask to form the etch stop layer 164 overlapping a channel region of the semiconductor layer 154 and the dielectric layer 167 overlapping the first electrode 127. Accordingly, the dielectric layer 167 is formed using the fourth mask that is used to form the etch stop layer 164. Thereafter, a conductive material such as a metal is stacked through sputtering or the like by using the fifth mask to form a data conductor including the source electrode 173, the drain electrode 175, the second electrode 177, and the second conductive layer 179. In this case, the second conductive layer 179 is directly connected to the first conductive layer 129 through the contact hole 89 formed using the third mask. This metal direct connection may be performed by using various wires of the peripheral area PA.

As such, the third mask is used to form the contact hole 89 for metal direct connection in removing the gate insulating layer 140 on the first electrode 127 of the capacitor, and the fourth mask is used to form the etch stop layer 164 in forming the dielectric layer 167. Therefore, it is not necessary to add a mask or add a process to form the thin dielectric layer 167 according to the present exemplary embodiment.

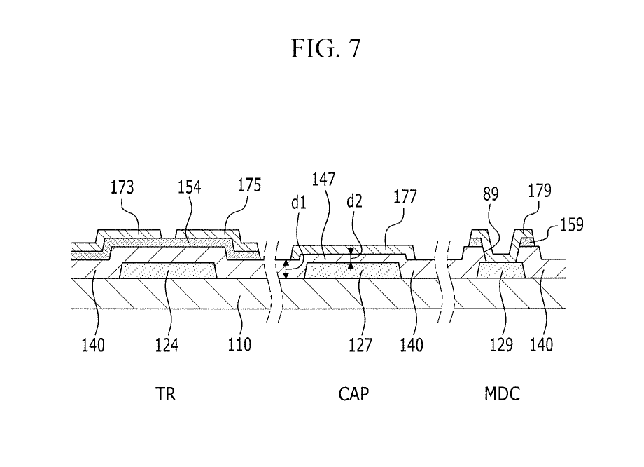

Hereinabove, the display device according to the exemplary embodiment of the present inventive concept has been described with reference to FIG. 2 to FIG. 5. Now, a display device according to an exemplary embodiment of the present inventive concept will be described with reference to FIG. 6.

FIG. 6 is a cross-sectional view corresponding to the cross-sectional view taken along the lines III-III′, IV-IV′, and V-V′ of FIG. 2 according to an exemplary embodiment of the present inventive concept.

FIG. 6 is similar to the exemplary embodiment of FIG. 3 because the direct connection of the metal to the transistor is the same. The examples of FIGS. 3 and 6 include capacitors that may have some structural variations. Specifically, in the exemplary embodiment of FIG. 3, in the capacitor, the gate insulating layer 140 slightly overlaps an edge of the first electrode 127. However, in the exemplary embodiment of FIG. 6, the gate insulating layer 140 is not overlapped with the first electrode 127, and it can be seen in FIG. 6 that the contact hole 87 is formed outside the first electrode 127. In this structure, the dielectric layer 167, which is formed of the same layer as the etch stop layer 164, completely covers the upper surface of the first electrode 127, and may cover at least one side surface of the first electrode 127.

As compared with the exemplary embodiment of FIG. 3, a distance between the first electrode 127 and the second electrode 177 may be uniform with a thickness of the dielectric layer 167 up to edges of the first electrode 127 and the second electrode 177, and thus such structure may result in the capacitance being increased. Meanwhile, the display device according to the exemplary embodiment of FIG. 6 may be manufactured by the manufacturing method described with reference to FIG. 4 and FIG. 5.

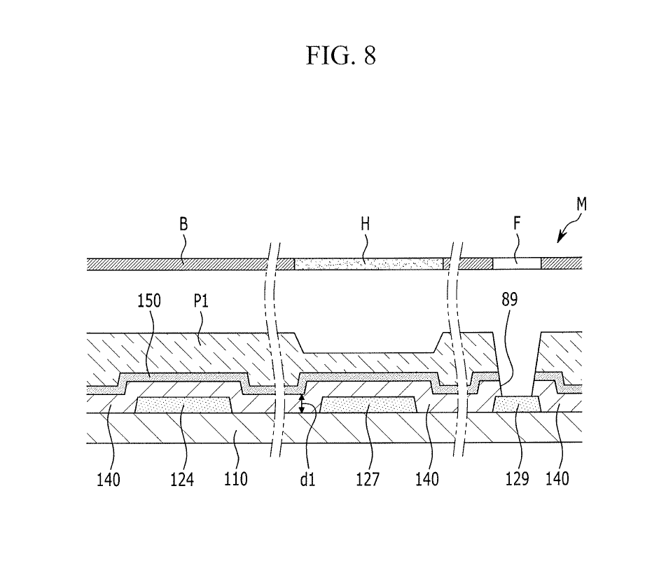

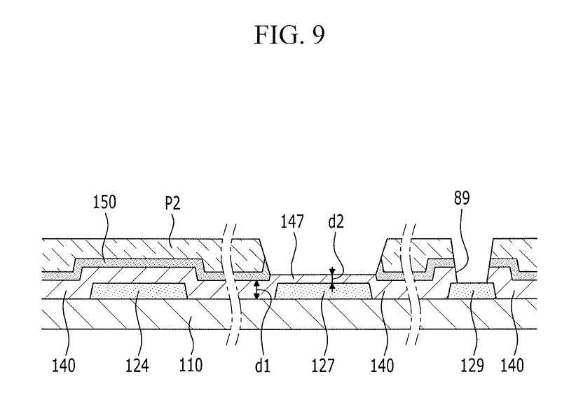

Hereinafter, a display device according to an exemplary embodiment of the present inventive concept will be described with reference to FIG. 7, FIG. 8 and FIG. 9. The description of similar or identical components to those of the described above may be simplified or omitted.

FIG. 7 is a cross-sectional view corresponding to the cross-sectional view taken along the lines III-III′, IV-IV′, and V-V′ of FIG. 2 according to an exemplary embodiment of the present inventive concept, and FIG. 8 and FIG. 9 are cross-sectional views illustrating a manufacturing method of the display device of FIG. 7.

Referring to FIG. 7, the gate electrode 124 of the transistor and the first electrode 127 and the first conductive layer 129 of the capacitor included in the gate conductor are disposed on the insulation substrate 110.

A gate insulating layer 140 is disposed on the gate conductor. The gate insulating layer 140 has a uniform thickness d1 as a whole, the thickness d2 on the first electrode 127 of the capacitor is relatively thinner than the thickness d1.

Whereas in the above description regarding FIG. 6, the gate insulating layer 140 on the first electrode 127 is completely removed, as shown in FIG. 7, the gate insulating layer 140 is reduced in thickness d2, and covers the electrode 127. Thus, the gate insulating layer shown in FIG. 7, which has the relatively thin thickness d2, provides a dielectric layer 147 of the capacitor disposed between the first electrode 127 and the second electrode 177 of the capacitor. The gate insulating layer 140 may have a multi-layer structure, and the dielectric layer 147 may have a single-layered structure. For example, the gate insulating layer 140 may be a multi-layer structure including a lower layer (e.g. first layer) made of a silicon nitride and an upper layer (e.g. second layer) made of a silicon oxide, and the dielectric layer 147 may be a single layer structure made of a silicon nitride.

As can also be seen in FIG. 7, the gate insulating layer 140 includes the contact hole 89, and the gate insulating layer 140 is formed so as to not cover at least a part of the first conductive layer 129.

A semiconductor layer 154 may be formed of a semiconductor material such as an oxide semiconductor, amorphous silicon, or polysilicon that may be disposed on the gate insulating layer 140 to overlap the gate electrode 124. A semiconductor layer 159 may also be disposed in a region where the first conductive layer 129 is disposed.

With continued reference to FIG. 7, a source electrode 173 and a drain electrode 175 are disposed on the semiconductor layer 154 of the transistor. A second electrode 177 is disposed on the dielectric layer 147 of the capacitor. A second conductive layer 179 of the capacitor is disposed on the first conductive layer 129 and is directly connected to the first conductive layer 129 through the contact hole 89.

The source electrode 173, the drain electrode 175, the second electrode 177, and the second conductive layer 179 are data conductors. The semiconductor layers 154 and 159 are disposed between the source electrode 173 and the drain electrode 175 of the data conductor and the gate insulating layer 140 and between the second conductive layer 179 and the gate insulating layer 140, but no semiconductor layer is located between the second electrode 177 and the dielectric layer 147, which is a thin gate insulating layer. As a result, a lower (e.g. second) surface of the dielectric layer 147 may be in contact with the first electrode 127, and an upper (e.g. first) surface of the dielectric layer 147 may be in contact with the second electrode 177. A barrier or resistive contact member may be disposed on the semiconductor layers 154 and 159.

Accordingly, the transistor TR including the gate electrode 124, the semiconductor layer 154, the source electrode 173, and the gate insulating layer 140 is disposed between the gate electrode 124 and the semiconductor layer 154. The capacitor includes the first electrode 127, the second electrode 177, and the dielectric layer 147 disposed there between. The dielectric layer 147 of the capacitor is the same layer as the gate insulating layer 140 of the transistor, but has a reduced thickness than the gate insulating layer 140 as shown in FIG. 7. Therefore, the distance between the first electrode 127 and the second electrode 177 is closer as compared with a case that the dielectric layer 147 of the capacitor having the same thickness as the gate insulating layer 140, and thus it is possible to increase the capacitance of the capacitor CAP. As a result, according to the present inventive concept, the capacitance can be maintained or increased even if the area of the capacitor is reduced, and the width of the gate driver can be reduced to decrease the width of the bezel of the display device. As such, formation of the dielectric layer 147 of the capacitor may be implemented without an additional mask. Hereinafter, a manufacturing method thereof will be described with reference to FIG. 8 and FIG. 9.

Referring to FIG. 8, a conductive material (such as a metal) is stacked on the insulation substrate 110 through sputtering or the like, and a gate conductor including the gate electrode 124, the first electrode 127, and the first conductive layer 129 is formed by performing patterning thereon with a photosensitive material such as a photoresist and a first mask.

Next, an insulating material, such as a silicon nitride or a silicon oxide, is stacked through chemical vapor deposition (CVD) to form the gate insulating layer 140. A semiconductor material such as an oxide semiconductor is stacked on the gate insulating layer 140 through sputtering or the like to form a semiconductor material layer 150.

Thereafter, a photosensitive material may be stacked on the semiconductor material layer 150, and a first photosensitive film pattern P1 including a portion having a different height may be formed by using a second mask M. The second mask M includes a completely transparent area F through which light is transmitted, a transflective area H through which only a part of light is transmitted, and a blocking area B where light is blocked. The second mask M may be, for example, a halftone mask or a slit mask in the transflective area H. In the case that a photosensitive material has positive photosensitivity that becomes a part to be removed when irradiated with light, a thicker portion of the first photosensitive film pattern P1 may be a portion corresponding to the blocking area B of the second mask M, and a thinner portion of the first photosensitive film pattern P1 may be an exposed portion corresponding to the transflective area H of the second mask M. A portion where the photosensitive material is completely removed so that the first photosensitive film pattern P1 is not formed may be referred to as an exposed portion corresponding to the complete transmission area F of the second mask M. When the photosensitive material has negative photosensitivity, the transparency of the second mask M corresponding to the first photosensitive film pattern P1 may be reversed.

As such, the first photoresist pattern P1 may be formed using the second mask M, and then the semiconductor material layer 150 and the gate insulation layer 140 may be etched using the first photoresist pattern P1 as an etching mask, such that the contact hole 89 is formed to expose at least a portion of the first conductive layer 129. In this case, another contact hole (not shown) that exposes the gate conductor to connect to the data conductor directly in the peripheral area (PA) of the display panel can be formed together therewith.

Referring to Next FIG. 9, a part of the first photosensitive film pattern P1 is etched to remove a thin portion. In this case, the thick portion of the first photosensitive film pattern P1 is also etched to reduce a width and a height to form a second photosensitive film pattern P2. As a result, the first-stacked photosensitive material may remain in the region corresponding to the transistor as the second photosensitive film pattern P2, and may be completely removed in a region corresponding to the first electrode 127. The semiconductor material layer 150 formed on the first electrode 127 is etched and removed using the second photoresist pattern P2 as an etching mask. Subsequently, the gate insulating layer 140 formed on the first electrode 127 is etched using the second photoresist pattern P2 as an etching mask so that the thickness thereof becomes thinner to form a dielectric layer 147 having a thickness d2 that is thinner than of the gate insulating layer 140. As such, while one second mask M is used to form the contact hole 89 that exposes at least a portion of the first conductive layer 129 for metal direct connection, the semiconductor material layer 150 disposed on the first electrode 127 may be removed and a thickness of the gate insulating layer 140 disposed on the first electrode 127 may be reduced. Thus, as shown in FIG. 9, the portion d2 is thinner than d1.

Thereafter, the data conductor including the source electrode 173, the drain electrode 175, the second electrode 177, and the second conductive layer 179 is formed by stacking a conductive material such as a metal and patterning the conductive material with a third mask. In this case, the second conductive layer 179 is directly connected with the first conductive layer 129 through the contact hole 89 formed by using the second mask M. This metal direct connection may be performed for various wires of the peripheral area PA. The semiconductor material layer 150 may also be patterned to form the semiconductor layer 154 of the transistor during patterning for the formation of the data conductor, and a halftone mask or a slit mask may be used as the third mask for this purpose.

As such, the second mask M used for forming the contact hole 89 for the metal direct connection is employed in reducing the thickness of the gate insulating layer 140 of the first electrode 127 of the capacitor by partially removing the gate insulating layer 140. Accordingly, the thin dielectric layer 147 according to the exemplary embodiment of the present inventive concept may be formed without an additional mask.

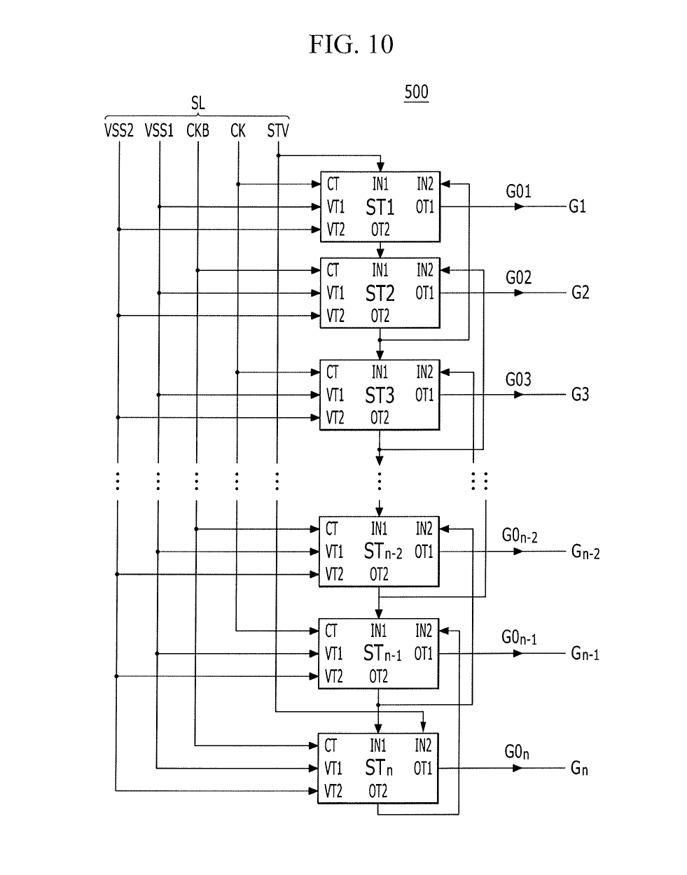

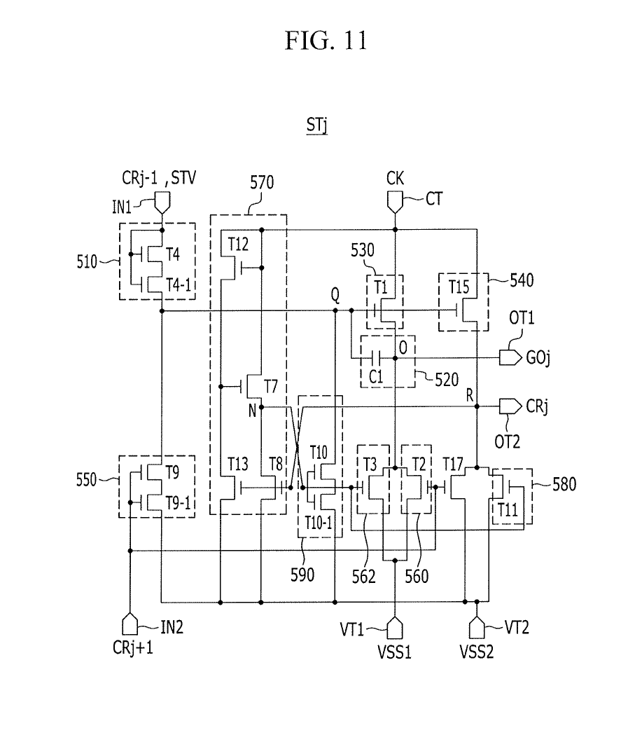

Hereinafter, a gate driver of a display device according to an exemplary embodiment of the present inventive concept will be described with reference to FIG. 10 and FIG. 11.

FIG. 10 is a block diagram illustrating a gate driver of a display device according to an exemplary embodiment of the present inventive concept, and FIG. 11 is a circuit diagram illustrating a stage of a gate driver according to an exemplary embodiment of the present inventive concept.

First, referring to FIG. 10, the gate driver 500 includes a plurality of stages ST1-STn that are connected to each other. The stages may be arranged in a cascaded arrangement, in which the output terminal of one stage is provided to an input terminal of the next stage, and typically in succession. These stages ST1 to STn are connected to a corresponding number of gate lines G1 to Gn to sequentially output gate signals to the gate lines G1 to Gn.

Each of the stages ST1 to STn includes a clock terminal CT, a first input terminal IN1, a second input terminal IN2, a first voltage terminal VT1, a second voltage terminal VT2, a first output terminal OT1, and a second output terminal (OT2).

The clock terminal CT receives a clock signal CKoran inverted clock signal CKB in which a phase of the clock signal CK is inverted. For example, clock terminals CT of odd-numbered stages ST1, ST3, . . . may receive clock signals CK, and clock terminals CT of even-numbered stages ST2, ST4, . . . may receive inverted clock signals CKB. The clock signals CK and the inverted clock signals CKB can be formed as high voltages and first low voltages VSS1.

A first input terminal IN1 is connected to a second output terminal OT2 of the front stage STj-1 in the j^{th} stage STj, which is one of the first to n^{th} stages ST1 to STn, and receives a signal CRj-1. However, since a first stage ST1 does not have a front stage, a vertical start signal STV is inputted into the first input terminal IN1.

A second input terminal IN2 of first stage ST1 is connected to the second output terminal OT2 of the succeeding stage ST(j+1) (in this case ST2) and receives the carry signal CR(j+1). However, since the n^{th} stage STn as shown in FIG. 10 is a last stage that does not have a rear stage, the vertical start signal STV is inputted into the second input terminal IN2. The vertical start signal STV inputted into the second input terminal IN2 of the n^{th} stage STn that may be a vertical start signal corresponding to the next frame.

The first voltage terminal VT1 receives the first low voltage VSS1. The first low voltage VSS1 has a first low level, and the first low level corresponds to a discharge level of the gate signal, e.g., about −6V.

In addition, the second voltage terminal VT2 receives a second low voltage VSS2 having a second low voltage level that is lower than the first low voltage level. For example, the second low level corresponds to a discharge level of a first contact Q (see FIG. 11) included in the stage, and may be, for example, about-10V.

The first output terminal OT1 is electrically connected to the corresponding gate line G1-Gn to output a gate signal. The first output terminals OT1 of the first to n^{th} stages ST1 to STn output the first to n^{th} gate signals GO1 to GOn, respectively. For example, the first output terminal OT1 of the first stage ST1 is electrically connected to the first gate line G1 to output the first gate signal GO1, and the first output terminal OT1 of the second stage ST2 is electrically connected to the second gate line G2 to output a second gate signal GO2. The first gate signal is output first, and then the second gate signal GO2 is output in a sequence. Next, the third to n^{th} gate signals GO3 to GOn are sequentially outputted.

The second output terminal OT2 outputs the carry signal CRj. The second output terminal OT2 of the front stage STj-1 is connected to the first input terminal IN1 of the main stage STj, and the second output terminal OT2 of the main stage SRj is connected to the second input terminal IN2 of the front stage STj-1.

Hereinafter, a stage STj of the gate driver of the display device according to an exemplary embodiment of the present inventive concept will be described with reference to FIG. 11.

The j^{th} stage STj of the gate driver of the display device according to an exemplary embodiment of the present inventive concept may include a buffer unit 510, a charge unit 520, a pull-up unit 530, a pull-down unit 560, an output node storage unit 562, a carry unit 540, a third node storage unit 580, an inverter unit 570, a discharge unit 550, and a first node storage unit 590.

The buffer unit 510 transmits, for example, a carry signal CR(j-1) of the previous stage to the pull-up unit 530. The buffer unit 510 may include a fourth transistor T4. The fourth transistor T4 may include a control terminal and an input terminal connected to the first input terminal IN1, and an output terminal connected to the first node Q (not shown).

The buffer unit 510 may further include a fourth additional transistor T4-1. The fourth additional transistor T4-1 may include the control terminal that is connected to the first input terminal IN1, the input terminal connected to the fourth transistor T4, and the output terminal is connected to the first node Q. In this case, the output terminal of the fourth transistor T4 may be connected to the input terminal of the fourth additional transistor T4-1 instead of the first node Q.

With continued reference to FIG. 11, the charge unit 520 includes a first capacitor C1 and is charged in response to the carry signal CR(j-1) of the previous stage provided by the buffer unit 510. A first terminal of the first capacitor C1 is connected to the first node Q and a second terminal is connected to the output node O of the gate signal. The first capacitor C1 may be one among a plurality of capacitors shown in FIG. 2, FIG. 6, and FIG. 7. When the high voltage of the carry signal CR(j-1) of the previous stage is received by the buffer unit 510, the charge unit 520 charges the first voltage corresponding to the high voltage.

The pull-up unit 530 outputs a gate signal. The pull-up unit 530 may include the first transistor T1. The first transistor T1 includes the control terminal connected to the first node Q, the input terminal connected to the clock terminal CT, and the output terminal connected to the output node O. The output node O is connected to the first output terminal OT1. The first transistor T1, for example, may be a transistor such as shown in FIG. 2, FIG. 6, and FIG. 7. The control terminal and the output terminal of the first transistor T1 are respectively connected to one terminal and the other terminal of the first capacitor C1.

In a state that the first voltage charged by the charge unit 520 is applied to the control terminal of the pull-up unit 530, when the high voltage of the clock signal CK is received by the clock terminal CT, the pull-up unit 530 is bootstrapped. In this case, the first node Q connected to the control terminal of the pull-up unit 530 is boosted from the first voltage to the boosting voltage. For example, the first node Q is first increased to the first voltage, and then is increased again to the boosting voltage.

While the boosting voltage is applied to the control terminal of the pull-up unit 530, the pull-up unit 530 outputs the high voltage of the clock signal CK as the high voltage of the j^{th} gate signal GOj. The j^{th} gate signal GOj is output through the first output terminal OT1 connected to the output node O.

With continued reference to FIG. 11, the pull-down unit 560 pulls down the j^{th} gate signal GOj. The pull-down unit 560 may include the second transistor T2. The second transistor T2 includes the control terminal connected to the second input terminal IN2, the input terminal connected to the output node O, and the output terminal connected to the first voltage terminal VT1. When the carry signal CR(j+1) of the next stage is received by the second input terminal IN2, the pull-down unit 560 pulls down the voltage of the output node O to the first low voltage VSS1 of the first voltage terminal VT1. In a previous non-limiting example, the first low voltage VSS1 may be, for example, −6 volts, whereas the second low voltage VSS2, may be, for example, −10 volts.

The output node storage unit 562 maintains the voltage of the output node O. The output node storage unit 562 may include the third transistor T3, as shown. The third transistor T3 includes the control electrode connected to the second node N, the input electrode connected to the output node O, and the output electrode connected to the first voltage terminal VT1. The output node storage unit 562 maintains the voltage of the output node O as the first low voltage VSS1 is applied to the first voltage terminal VT1 in response to the signal of the second node N. The voltage of the output node O that is pulled down to the first low voltage VSS1 by the output node storage unit 562 may be stably maintained. The output node storage unit 562 may be omitted.

The carry unit 540 outputs the carry signal CRj. The carry unit 540 may include the fifteenth transistor T15. The fifteenth transistor T15 includes the control terminal connected to the first node Q, the input terminal connected to the clock terminal CT, and the output terminal connected to the third node R. The third node R is connected to the second output terminal OT2.

The carry unit 540 may further include a capacitor (not shown) connecting the control terminal and the output terminal. When the high voltage is applied to the first node Q, the carry unit 540 outputs the high voltage of the clock signal CK received by the clock terminal CT to the carry signal CRj. The carry signal CRj is output through the second output terminal OT2 connected to the third node R.

The third node storage unit 580 maintains the voltage of the third node R. The third node storage unit 580 may include the eleventh transistor T11. The eleventh transistor T11 includes the control terminal connected to the second node N, the input terminal connected to the third node R, and the output terminal connected to the second voltage terminal VT2. The third node storage unit 580 maintains the voltage of the third node R as the second low voltage VSS2 in response to the signal of the second node N.

The inverter unit 570 (including the twelfth transistor T12) applies the signal having the same phase as the clock signal CK received by the clock terminal CT to the second node N during a period except for the output period of the carry signal CRj. In addition to the twelfth transistor T12, the inverter unit may also include the seventh transistor T7, the thirteenth transistor T13, and the eighth transistor T8.

The twelfth transistor T12, for example, includes the control terminal and the input terminal connected to the clock terminal CT and the output terminal connected to the input terminal of the thirteenth transistor T13 and the control terminal of the seventh transistor T7.

The seventh transistor T7 includes the control terminal connected to the thirteenth transistor T13, the input terminal connected to the clock terminal CT, and the output terminal connected to the input terminal of the eighth transistor T8. The output terminal of the seventh transistor T7 is also connected to the second node N.

With regard to the inverter, the thirteenth transistor T13 includes the control terminal connected to the third node R, the input terminal connected to the twelfth transistor T12, and the output terminal connected to the second voltage terminal VT2. The eighth transistor T8 includes the control terminal connected to the third node R, the input terminal connected to the second node N, and the output terminal connected to the second voltage terminal VT2.

While the high voltage is applied to the third node R, the inverter unit 570 discharges the clock signal CK received by the clock terminal CT to the second low voltage VSS2 applied to the second voltage terminal VT2. For example, in response to the high voltage of the third node R, the eighth and thirteenth transistors T8 and T13 are turned on, and thereby the clock signal CK is discharged to the second low voltage VSS2. Accordingly, the value of the second node N that is the output node of the inverter unit 570 is maintained as the second low voltage VSS2 while the j^{th} gate signal GOj is output.

In response to the carry signal CR(j+1) of the next stage, the discharge unit 550 discharges the high voltage of the first node Q to the second low voltage VSS2 of the lower level that is lower than the first low voltage VSS1. The discharge unit 550 may include the ninth transistor T9. The ninth transistor T9 includes the control terminal connected to the second input terminal IN2, the input terminal connected to the first node Q, and the output terminal connected to the second voltage terminal VT2.

The discharge unit 550 may further include the ninth additional transistor T9-1. The ninth additional transistor T9-1 may include the control terminal connected to the second input terminal IN2, the input terminal connected to the ninth transistor T9, and the output terminal connected to the second voltage terminal VT2. In this case, the output terminal of the ninth transistor T9 may be connected to the input terminal of the ninth additional transistor T9-1 instead of the second voltage terminal VT2.

When the carry signal CR(j+1) of the next stage is applied to the second input terminal IN2, the discharge unit 550 discharges the voltage of the first node Q to the second low voltage VSS2 applied to the second voltage terminal VT2. Accordingly, the voltage of the first node Q is increased from the first voltage to the boosting voltage and then is decreased to the second low voltage VSS2.

In the above configuration, the output terminal of the ninth transistor T9 is connected to the second voltage terminal VT2, however the output terminal of the ninth transistor T9 may be connected to the first voltage terminal VT1.

The first node storage unit 590 maintains the voltage of the first node Q. The first node storage unit 590 may include the tenth transistor T10. The tenth transistor T10 includes the control terminal connected to the second node N, the input terminal connected to the first node Q, and the output terminal connected to the second voltage terminal VT2.

The first node storage unit 590 may further include a tenth additional transistor T10-1. The tenth additional transistor T10-1 includes the control terminal connected to the second node N, the input terminal connected to the tenth additional transistor T10, and the output terminal connected to the second voltage terminal VT2. In this case, as shown in FIG. 11, the output terminal of the tenth transistor T10 may be connected to the input terminal of the tenth additional transistor T10-1. The first node storage unit 590 maintains the voltage of the first node Q as the second low voltage VSS2 in response to the signal of the second node N.

While the inventive concept has been described in connection with what is presently considered certain exemplary embodiments of the inventive concept, it is to be understood that the inventive concept is not limited to the disclosed embodiments, but, on the contrary, is intended to cover various modifications and equivalent arrangements included within the spirit and scope of the appended claims.

What is claimed is:

1. A display device comprising:
a substrate;
a transistor disposed on the substrate including a gate electrode, a semiconductor layer, a source electrode, a drain electrode, and a gate insulating layer disposed between the gate electrode and the semiconductor layer; and
a capacitor disposed on the substrate including a first electrode, a second electrode, and a dielectric layer disposed between the first electrode and the second electrode,
wherein the dielectric layer has a thickness that is less than a thickness of the gate insulating layer.

2. The display device of claim 1, wherein the substrate includes a display area in which a plurality of pixels are disposed and a peripheral area in which a gate driver including the transistor and the capacitor is disposed, and wherein the dielectric layer of the capacitor is a separate layer from the gate insulating layer.

3. The display device of claim 1, wherein the dielectric layer of the capacitor is a separate layer from the gate insulating layer.

4. The display device of claim 1, wherein the gate insulating layer has at least one contact hole formed therein,
wherein a first conductive layer comprising gate lines is disposed on the substrate, and a second conductive layer comprising data lines is connected to the first conductive layer through a metal direct connection via the at least one contact hole, and
wherein the second conductive layer is an extension of the second electrode.

5. The display device of claim 1, wherein the transistor further includes an etch stop layer disposed on the semiconductor layer, and
the dielectric layer is disposed at a same layer as the etch stop layer.

6. The display device of claim 5, wherein the dielectric layer is formed of a same material as the etch stop layer.

7. The display device of claim 6, wherein the thickness of the dielectric layer is substantially the same as a thickness of the etch stop layer.

8. The display device of claim 7, wherein the thickness of the dielectric layer is in a range of about 400 angstroms to about 600 angstroms.

9. The display device of claim 1, wherein the dielectric layer is formed as a single layer.

10. The display device of claim 9, wherein the single layer of the dielectric layer is formed of a silicon oxide.

11. The display device of claim 9, wherein the dielectric layer includes a silicon oxide.

12. The display device of claim 11, wherein the dielectric layer has a first surface that contacts an upper surface of the first electrode and a second surface that contacts a lower surface of the second electrode.

13. The display device of claim 12, wherein the dielectric layer covers at least one side surface of the first electrode.

14. The display device of claim 9, wherein the dielectric layer includes a silicon nitride.

15. The display device of claim 1, wherein the substrate includes a display area in which a plurality of pixels are disposed and a peripheral area in which a gate driver is disposed, and
the gate driver includes the transistor and the capacitor.

16. The display device of claim 15, wherein the first electrode of the capacitor is connected with the gate electrode of the transistor, and the second electrode of the capacitor is connected with the drain electrode of the transistor.

17. A display device comprising:
a substrate;
a gate driver including a transistor and a capacitor, the transistor disposed on the substrate including a gate electrode, a semiconductor layer, a source electrode, a drain electrode, and a gate insulating layer disposed between the gate electrode and the semiconductor layer;
the capacitor is disposed on the substrate and includes a first electrode and a second electrode and a dielectric layer disposed between the first electrode and the second electrode; and
wherein the dielectric layer is a separate layer from the gate insulating layer, and a thickness of the dielectric layer is less than a thickness of the gate insulating layer.

18. The display device according to claim 17, wherein the substrate includes a display area in which a plurality of pixels are disposed and a peripheral area in which a gate driver including the transistor and the capacitor is disposed.

19. The display device according to claim 18, wherein the transistor further includes an etch stop layer disposed on the semiconductor layer, and
the dielectric layer is disposed at a same layer as the etch stop layer and formed of a same material as the etch stop layer.

20. The display device according to claim 19, wherein the thickness of the dielectric layer is substantially the same as a thickness of the etch stop layer.
